(19) United States
(12) Patent Application Publication
(10) Pub. No.: US 2026/0186401 A1
(43) Pub. Date: Jul. 2, 2026

(54) PELLICLE MEMBRANE AND METHOD OF MANUFACTURE

(71) Applicant: ASML NETHERLANDS B.V., Veldhoven (NL)

(72) Inventors: Zomer Silvester HOUWELING, Utrecht (NL); Mahnaz GHIASI KABIRI, Beverwijk (NL); Adrianus Johannes Maria GIESBERS, Vlijmen (NL); Abhinav JAIN, Eindhoven (NL)

(73) Assignee: ASML NETHERLANDS B.V., Veldhoven (NL)

(21) Appl. No.: 19/131,042

(22) PCT Filed: Nov. 1, 2023
(86) PCT No.: PCT/EP2023/080443

§ 371 Date: May 19, 2025

(30) Foreign Application Priority Data
Dec. 13, 2022 (EP) 2213011.4

(51) Int. Cl. G03F 1/62; G03F 7/00

(52) U.S. Cl. CPC G03F 1/62; G03F 7/70983

(57) ABSTRACT

A pellicle membrane includes thermally emissive crystals supported by a matrix, wherein the average thickness of the pellicle membrane is greater than the average grain size of the emissive crystals. Also, there is described a pellicle assembly including such a pellicle membrane, and a lithographic apparatus including such a pellicle membrane or pellicle assembly. Also described is a method of manufacturing a pellicle membrane including emissive crystals in a matrix, the method including controlling at least one selected from: the chemical composition of the emissive crystals, morphology of the emissive crystals, and/or annealing conditions to provide a pellicle membrane having a thickness greater than the average grain size of the emissive crystals.

### CROSS-REFERENCE TO RELATED APPLICATIONS

This application claims priority of EP application 22213011.4 which was filed on 13 Dec. 2022, and which is incorporated herein in its entirety by reference.

### FIELD

The present invention relates to a pellicle membrane for a lithographic apparatus, a pellicle assembly for a lithographic apparatus, method of manufacturing a pellicle membrane, and the use of such a pellicle membrane, pellicle assembly or method in a lithographic apparatus or method. The present invention has particular, but not exclusive, application to EUV lithographic apparatuses and methods.

### BACKGROUND

A lithographic apparatus is a machine constructed to apply a desired pattern onto a substrate. A lithographic apparatus can be used, for example, in the manufacture of integrated circuits (ICs). A lithographic apparatus may for example project a pattern from a patterning device (e.g. a mask) onto a layer of radiation-sensitive material (resist) provided on a substrate.

The wavelength of radiation used by a lithographic apparatus to project a pattern onto a substrate determines the minimum size of features which can be formed on that substrate. A lithographic apparatus which uses EUV radiation, being electromagnetic radiation having a wavelength within the range 4-20 nm, may be used to form smaller features on a substrate than a conventional lithographic apparatus (which may for example use electromagnetic radiation with a wavelength of 193 nm).

A lithographic apparatus includes a patterning device (e.g. a mask or reticle). Radiation is provided through or reflected off the patterning device to form an image on a substrate. A membrane assembly, also referred to as a pellicle, may be provided to protect the patterning device from airborne particles and other forms of contamination. Contamination on the surface of the patterning device can cause manufacturing defects on the substrate.

Pellicles may also be provided for protecting optical components other than patterning devices. Pellicles may also be used to provide a passage for lithographic radiation between regions of the lithography apparatus which are sealed from one another. Pellicles may also be used as filters, such as spectral purity filters or as part of a dynamic gas lock of a lithographic apparatus.

A mask assembly may include the pellicle which protects a patterning device (e.g. a mask) from particle contamination. The pellicle may be supported by a pellicle frame, forming a pellicle assembly. The pellicle may be attached to the frame, for example, by gluing or otherwise attaching a pellicle border region to the frame. The frame may be permanently or releasably attached to a patterning device.

Due to the presence of the pellicle in the optical path of the EUV radiation beam, it is necessary for the pellicle to have high EUV transmissivity. A high EUV transmissivity allows a greater proportion of the incident radiation through the pellicle. In addition, reducing the amount of EUV radiation absorbed by the pellicle may decrease the operating temperature of the pellicle. Since transmissivity is at least partially dependent on the thickness of the pellicle, it is desirable to provide a pellicle which is as thin as possible whilst remaining reliably strong enough to withstand the sometimes hostile environment within a lithography apparatus.

It is therefore desirable to provide a pellicle which is able to withstand the harsh environment of a lithographic apparatus, in particular an EUV lithography apparatus. It is particularly desirable to provide a pellicle which is able to withstand higher powers than previously. It is also desirable to provide pellicle membranes which are less susceptible to damage caused by shocks.

Whilst the present application generally refers to pellicles in the context of lithography apparatus, in particular EUV lithography apparatus, the invention is not limited to only pellicles and lithography apparatus and it is appreciated that the subject matter of the present invention may be used in any other suitable apparatus or circumstances.

For example, the methods of the present invention may equally be applied to spectral purity filters. Some EUV sources, such as those which generate EUV radiation using a plasma, do not only emit desired ‘in-band’ EUV radiation, but also undesirable (out-of-band) radiation. This out-of-band radiation is most notably in the deep UV (DUV) radiation range (100 to 400 nm). Moreover, in the case of some EUV sources, for example laser produced plasma EUV sources, the radiation from the laser, usually at 10.6 microns, presents a significant out-of-band radiation.

In a lithographic apparatus, spectral purity is desired for several reasons. One reason is that the resist is sensitive to out of-band wavelengths of radiation, and thus the image quality of patterns applied to the resist may be deteriorated if the resist is exposed to such out-of-band infrared radiation. Furthermore, out-of-band radiation infrared radiation, for example the 10.6 micron radiation in some laser produced plasma sources, leads to unwanted and unnecessary heating of the patterning device, substrate, and optics within the lithographic apparatus. Such heating may lead to damage of these elements, degradation in their lifetime, and/or defects or distortions in patterns projected onto and applied to a resist-coated substrate.

A typical spectral purity filter may be formed, for example, from a silicon foundation structure (e.g. a silicon grid, or other member, provided with apertures) that is coated with a reflective metal, such as molybdenum. In use, a typical spectral purity filter might be subjected to a high heat load from, for example, incident infrared and EUV radiation. The heat load might result in the temperature of the spectral purity filter being above 800° C. Thus, the spectral purity filter may be used as a pellicle, and vice versa. Therefore, reference in the present application to a ‘pellicle’ is also reference to a ‘spectral purity filter’. Although reference is primarily made to pellicles in the present application, all of the features could equally be applied to spectral purity filters.

The present invention has been devised in an attempt to address at least some of the problems identified above.

### SUMMARY OF THE INVENTION

According to a first aspect of the present disclosure, there is provided a pellicle membrane comprising thermally emissive crystals supported by a matrix, wherein the average thickness of the pellicle membrane is greater than the average grain size of the emissive crystals.

A pellicle as a device has a set of performance specifications, which are secured by functionalities of its constituent materials. Relevant performance specifications are the requirement that the pellicle does not distort imaging, sufficiently transmits EUV light (EUVT), and that it does not contaminate critical components in the scanner. Multiple different types of pellicle exist, including ones which comprise either a single material core with added layers of individual required functionalities or a single layer that exhibits multiple functionalities.

For a multilayer membrane the individual functionalities can be tuned by the individual layers, whereby changing parameters in one layer may alter the restrictions on another layer in the stack to have conformal performance of the entire multi-stack. For example, raising the thickness of one layer results in smaller thickness limits of the others layers to reach sufficient EUV transmissivity. On the other hand, for a single layer membrane, tuning of individual functionalities is not readily possible, unless another material component is added to the material that alters at least one functionality to a greater extent than the other functionalities. The addition of a material component, in the form of a dopant or alloying element, can bring about phase segregation or phase separation, and that can result in a distribution of individual functionalities over the different phases. A membrane with such segregated or separated phases is called a composite pellicle.

An example of a single-layer multi-phase pellicle is a pellicle in which molybdenum silicide MoSix crystals primarily provide high thermal emissivity, high ductility and high stiffness, which are all beneficial properties. The MoSix crystals, however, also provide high brittleness of the pellicle and a very high mechanical pre-tension, which are not preferred. Herein MoSix includes various stoichiometries such as MoSi₂, Mo₅Si₃, and Mo₃Si silicides of molybdenum.

Such pellicle membranes can be susceptible to shocks, which can lead to damage or rupture of the pellicle membrane. Without wishing to be bound by scientific theory, it is believed that composite pellicles which include a crystalline phase supported in a matrix, which may itself be crystalline or non-crystalline, are susceptible to shock due to the defects present in the crystals therein. Defects include twin boundaries, dislocations, and stack faults, amongst others. Larger crystals have an increased number of faults which pile-up at the edges, resulting in a smaller force required to push dislocations to the next grain, which may then result in inception and propagation of a crack and consequent material failure. It has been found that material failure of existing pellicle membranes occurs along the grain boundaries, rather than through the crystal grains. As such, decreasing the grain size whilst maintaining the other elements of a pellicle membrane unchanged may be expected to improve yield strength. However, this is not observed in practice.

Existing pellicle membranes include emissive crystals which have grain sizes which are large enough to span the thickness of the membrane. It has been found that by having a pellicle membrane in which the thickness of the membrane is more than the thickness of the emissive crystals therein, provides for improved shock resistance. This realisation also provides a lower limit on the thickness of a pellicle membrane as in cases where the thickness is essentially one crystal grain thick, there is an elevated likelihood of weak spots, stress concentrations, and is therefore very susceptible to mechanical shocks.

The thickness of the pellicle membrane is at least 1.5 times the average grain size of the emissive crystals. By having the pellicle membrane thickness greater than the average grain size of the emissive crystals, the risk of weak spots, stress concentrations and the like is reduced.

The thickness of the pellicle membrane may be in the range of from around 5 nm to around 30 nm. As such, the average grain size of the emissive crystals in the pellicle membrane is less than this.

The pellicle membrane may comprise MoSiSi—X, MoSiC—X or MoSiN—X, wherein X is selected from N, Y, O, S, C, Hf, Nb, W, Ta, Zr, or combinations thereof. It has been found that the addition of such elements provides for smaller emissive crystals to be formed. In this way, it is possible to tune the dimensions of the emissive crystals such that they are smaller than the thickness of the pellicle membrane. It will be appreciated that doping of MoSiN with N and doping of MoSiC with C are disclaimed on the basis that such pellicle membranes have already had N or C included.

The emissive crystals may comprise a content of around 20 to around 22 at % Mo. A reduction in Mo content in an emissive crystal from more than 22at % down to 20at % or less results in a halving of grain size whilst maintaining advantageous emissivity and transmissivity. As such, it is possible to provide a pellicle membrane which has the desired emissivity and transmissivity characteristics, but which has grain sizes that allow the emissive crystals to be less than the thickness of the pellicle membrane.

For a MoSiSi composite pellicle, the pellicle core may comprise a content of around 3 to around 13 at % N. It has been found that the addition of N to the core results in roughly a halving of the grain size of the emissive crystals.

The pellicle membrane includes at least two layers of single or multiple crystal grain thickness, separated by a separation layer. Grain size reduction can be brought about by, instead of making a single layer deposition, making a layer deposition with a division overlayer, and next a second deposition layer, such that the first and second deposition layers are separated by the division layer. This holds for any composite pellicle, including MoSi-based and non-MoSi based composite pellicles.

If a composite pellicle membrane comprises two crystalline phases and only one of the crystalline phases allows grain size reduction (whereby the other type of grains remain unaffected and thus remain relatively large) then the thickness of the pellicle may be divided into two sections of reduced grain sizes separated by a separation layer.

The pellicle membrane may include a cap layer on one or both sides of the pellicle membrane. It will be appreciated that a membrane has two sides or faces. A cap layer may be provided on one or both sides or faces in order to protect the pellicle membrane from the environment within the lithographic apparatus. Any known cap layer may be provided and the present disclosure is not limited to any particular cap layer.

The emissive crystals may be non-rounded. The morphology of the emissive crystals may be selected to provide robustness to the pellicle membrane. With diminishing grain size, there is an increased likelihood of grain slippage and creep, which occurs when grains slide over one another. Grains with a rounded morphology slip more readily than grains which has a more irregular shape. As such, by providing non-rounded grains, slippage and creep can be reduced. The addition of elements such as C results in irregularly shaped emissive crystal grains.

The average grain size of the emissive crystals may be 20 nm or less, 18 nm or less, 15 nm or less, 12 nm or less, 10 nm or less, 8 nm or less, less 5 nm or less, 3 nm or less, 2 nm or less, or 1 nm or less, or from 1 to 20 nm, from 2-18 nm, from 5-15 nm, or from 8-12 nm, or from 8 to 10 nm. Preferably the average grain size is 1.5 times less than the thickness of the pellicle membrane. For example, where the pellicle membrane is 15 nm in thickness, the average grain size of the emissive crystal is 15 nm/1.5=10 nm or less. As such, the average grain size is the average thickness of pellicle membrane/1.5, or less. The denominator may be 1.5 or greater, for example 1.6, 1.7, 1.8, 1.9, or 2.0. Preferably, the pellicle thickness does not include the thickness of any capping layer(s).

According to a second aspect of the present disclosure, there is provided a pellicle assembly comprising a pellicle membrane according to the first aspect. The pellicle assembly may include additional elements as conventionally found in pellicle assemblies. For example, the pellicle assembly may include a frame via which the pellicle membrane may be supported.

According to a third aspect of the present disclosure, there is provided a lithographic apparatus comprising a pellicle membrane according to the first aspect or a pellicle assembly according to the second aspect of the present disclosure.

According to a fourth aspect of the present disclosure, there is provided a method of manufacturing a pellicle membrane including emissive crystals in a matrix, the method including controlling at least one of the chemical composition of the emissive crystals, morphology of the emissive crystals, and annealing conditions to provide a pellicle membrane having a thickness greater than the average grain size of the emissive crystals.

As described in respect of the first aspect of the present disclosure, it has been found that having a pellicle membrane in which the thickness of the pellicle membrane is greater than the average grain size of emissive crystals therein is advantageous. This can be achieved by adjusting the chemical composition of the emissive crystals, adjusting the morphology of the emissive crystals, and/or adjusting the annealing conditions.

The morphology of the emissive crystals may be controlled such that the emissive crystals are non-rounded. This can be achieved, for example, by including an element, such as C.

The emissive crystals include at least one metal, and the concentration of the metal may be adjusted to control the grain size of the emissive crystals. For example, as described in relation to the first aspect of the present disclosure, the metal may be Mo, and the concentration of Mo may be from around 20 to around 22 at % Mo.

The method may include including nitrogen in the core to control the grain size of the emissive crystals. The pellicle core comprises the matrix and emissive crystals.

The method may include incorporating one or more of N, Y, O, S, C, Hf, Nb, W, Ta, Zr, or combinations thereof in the pellicle core to control the grain size of the emissive crystals.

The method may include controlling the annealing temperature during manufacturing to control the grain size of the emissive crystals. During manufacture of a pellicle membrane, the membrane is annealed to create crystal growth. Crystal grain size increases at higher temperature and crystallisation is observed from around 650-700° C. If the annealing time is maintained and only the temperature is changed, it is observed that larger crystals are formed at higher temperatures. As such, the annealing temperature is preferably from around 650 to around 750° C.

The method may include providing at least two layers of separated by a separation layer wherein the thickness of one, both, or all of the layers is greater than the average grain size of the emissive crystals. As described in respect of the first aspect of the present disclosure, a multi-layered pellicle membrane may be manufactured which includes two layers having emissive crystals of reduced grain size separated by a division layer.

The method may include controlling the morphology of the emissive crystals by including an element, such as carbon, to provide irregularly shaped grains.

According to a fifth aspect of the present disclosure, there is provided use of a pellicle membrane according to the first aspect, a pellicle assembly according to the second aspect, a lithographic apparatus according to the third aspect, or a method according to the fourth aspect of the present disclosure in a lithographic apparatus or method.

It will be appreciated that features described in respect of one embodiment may be combined with any features described in respect of another embodiment and all such combinations are expressly considered and disclosed herein.

It will also be appreciated that the present disclosure applies to single-layer pellicles, multi-layer pellicles, single-layer single-phase pellicles, single-layer multi-phase pellicles, multi-layer multi-phase pellicles, molybdenum-silicon pellicles, metal-silicon pellicles, as well as pellicles containing a metal, or a metal and a second element. The pellicles may be EUV pellicles.

### BRIEF DESCRIPTION OF THE DRAWINGS

Embodiments of the invention will now be described, by way of example only, with reference to the accompanying schematic drawing in which corresponding reference symbols indicate corresponding parts, and in which:

FIG. 1 depicts a lithographic apparatus according to an embodiment of the invention; and

FIG. 2 depicts a pellicle assembly with a composite film;

FIG. 3 is a transmission electron microscope image of a MoSiSi composite pellicle membrane in (top) cross-section and (bottom) side view;

FIG. 4 is a schematic depiction of the pellicle membrane shown in FIG. 3;

FIG. 5 is a top-view STEM image of a molybdenum silicide (MoSiSi) pellicle membrane;

FIG. 6 is a schematic depiction of options for increasing the robustness of a pellicle membrane;

FIG. 7 depicts a comparison of grain size of molybdenum silicide crystals with and without nitrogen for a MoSiSi pellicle; and

FIG. 8 shows various scanning electron microscopy images of MoSiSi pellicle membranes of different thicknesses which have been annealed at different temperature.

The features and advantages of the present invention will become more apparent from the detailed description set forth below when taken in conjunction with the drawings, in which like reference characters identify corresponding elements throughout. In the drawings, like reference numbers generally indicate identical, functionally similar, and/or structurally similar elements.

### DETAILED DESCRIPTION

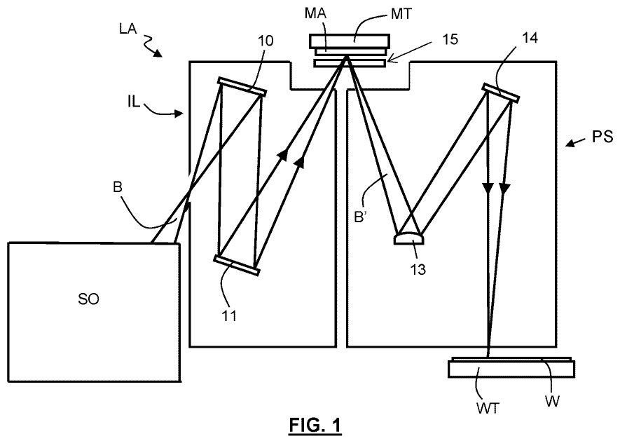

FIG. 1 shows a lithographic system including a pellicle 15 (also referred to as a membrane assembly) according to the present invention. The lithographic system comprises a radiation source SO and a lithographic apparatus LA. The radiation source SO is configured to generate an extreme ultraviolet (EUV) radiation beam B. The lithographic apparatus LA comprises an illumination system IL, a support structure MT configured to support a patterning device MA (e.g. a mask), a projection system PS and a substrate table WT configured to support a substrate W. The illumination system IL is configured to condition the radiation beam B before it is incident upon the patterning device MA. The projection system is configured to project the radiation beam B (now patterned by the mask MA) onto the substrate W. The substrate W may include previously formed patterns. Where this is the case, the lithographic apparatus aligns the patterned radiation beam B with a pattern previously formed on the substrate W. In this embodiment, the pellicle 15 is depicted in the path of the radiation and protecting the patterning device MA. It will be appreciated that the pellicle 15 may be located in any required position and may be used to protect any of the mirrors in the lithographic apparatus.

The radiation source SO, illumination system IL, and projection system PS may all be constructed and arranged such that they can be isolated from the external environment. A gas at a pressure below atmospheric pressure (e.g. hydrogen) may be provided in the radiation source SO. A vacuum may be provided in illumination system IL and/or the projection system PS. A small amount of gas (e.g. hydrogen) at a pressure well below atmospheric pressure may be provided in the illumination system IL and/or the projection system PS.

The radiation source SO shown in FIG. 1 is of a type which may be referred to as a laser produced plasma (LPP) source. A laser, which may for example be a CO₂ laser, is arranged to deposit energy via a laser beam into a fuel, such as tin (Sn) which is provided from a fuel emitter. Although tin is referred to in the following description, any suitable fuel may be used. The fuel may for example be in liquid form, and may for example be a metal or alloy. The fuel emitter may comprise a nozzle configured to direct tin, e.g. in the form of droplets, along a trajectory towards a plasma formation region. The laser beam is incident upon the tin at the plasma formation region. The deposition of laser energy into the tin creates a plasma at the plasma formation region. Radiation, including EUV radiation, is emitted from the plasma during de-excitation and recombination of ions of the plasma.

The EUV radiation is collected and focused by a near normal incidence radiation collector (sometimes referred to more generally as a normal incidence radiation collector). The collector may have a multilayer structure which is arranged to reflect EUV radiation (e.g. EUV radiation having a desired wavelength such as 13.5 nm). The collector may have an elliptical configuration, having two ellipse focal points. A first focal point may be at the plasma formation region, and a second focal point may be at an intermediate focus, as discussed below.

The laser may be separated from the radiation source SO. Where this is the case, the laser beam may be passed from the laser to the radiation source SO with the aid of a beam delivery system (not shown) comprising, for example, suitable directing mirrors and/or a beam expander, and/or other optics. The laser and the radiation source SO may together be considered to be a radiation system.

Radiation that is reflected by the collector forms a radiation beam B. The radiation beam B is focused at a point to form an image of the plasma formation region, which acts as a virtual radiation source for the illumination system IL. The point at which the radiation beam B is focused may be referred to as the intermediate focus. The radiation source SO is arranged such that the intermediate focus is located at or near to an opening in an enclosing structure of the radiation source.

The radiation beam B passes from the radiation source SO into the illumination system IL, which is configured to condition the radiation beam. The illumination system IL may include a facetted field mirror device 10 and a facetted pupil mirror device 11. The faceted field mirror device 10 and faceted pupil mirror device 11 together provide the radiation beam B with a desired cross-sectional shape and a desired angular distribution. The radiation beam B passes from the illumination system IL and is incident upon the patterning device MA held by the support structure MT. The patterning device MA reflects and patterns the radiation beam B. The illumination system IL may include other mirrors or devices in addition to or instead of the faceted field mirror device 10 and faceted pupil mirror device 11.

Following reflection from the patterning device MA the patterned radiation beam B enters the projection system PS. The projection system comprises a plurality of mirrors 13, 14 which are configured to project the radiation beam B onto a substrate W held by the substrate table WT. The projection system PS may apply a reduction factor to the radiation beam, forming an image with features that are smaller than corresponding features on the patterning device MA. A reduction factor of 4 may for example be applied. Although the projection system PS has two mirrors 13, 14 in FIG. 1, the projection system may include any number of mirrors (e.g. six mirrors).

The radiation sources SO shown in FIG. 1 may include components which are not illustrated. For example, a spectral filter may be provided in the radiation source. The spectral filter may be substantially transmissive for EUV radiation but substantially blocking for other wavelengths of radiation such as infrared radiation.

In an embodiment the membrane assembly 15 is a pellicle for the patterning device MA for EUV lithography. The membrane assembly 15 of the present invention can be used for a dynamic gas lock or for a pellicle or for another purpose. In order to ensure maximized EUV transmission and minimized impact on imaging performance it is preferred that the membrane is only supported at the border.

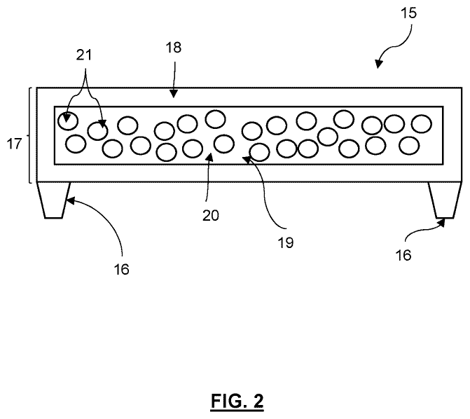

FIG. 2 is a schematic depiction of a pellicle assembly 15 in accordance with the present disclosure. The pellicle assembly includes a support 16 that is configured to support the pellicle membrane 17. In the figure, the support 16 appears as two separate elements, although this does not necessarily have to be the case and the support 16 may be in the form of a border which circumscribes the pellicle membrane 17. The pellicle membrane 17 includes a cap layer 18 that is configured to protect the pellicle membrane 17, particularly the emissive layer 19, from degradation. The cap layer may be any known cap layer and the present disclosure is not particularly limited to any specific cap layer material. The emissive layer 19 includes a matrix 20, which provides the required pre-tension and strength. Pre-tension is required since the pellicle membrane 17 is subjected to a pressure differential in use and it is necessary to accommodate such a differential. The matrix material 20 may include one or more of elemental silicon, silicon oxide, silicon fluoride, silicon sulphide, or silicon selenide. The emissive layer 19 includes thermally emissive crystals 21 disposed within the matrix 20. The thermally emissive crystals 21 are includes to increase the thermal emissivity of the pellicle membrane 17, thereby allowing it to operate at a lower temperature at a given power than would be the case otherwise, or to operate at the same temperature as pellicle membranes not including emissive crystals, but at a higher power. The thermally emissive crystals 21 may include one or more of a metal carbide, a metal boride, a metal nitride, a metal fluoride, a metal silicide, or a metal. The metal may be selected from one or more of molybdenum, zirconium, yttrium, lanthanum, scandium, niobium, iridium, chromium, vanadium, platinum, rhodium, hafnium, and ruthenium.

If the patterning device MA is left unprotected, the contamination can require the patterning device MA to be cleaned or discarded. Cleaning the patterning device MA interrupts valuable manufacturing time and discarding the patterning device MA is costly. Replacing the patterning device MA also interrupts valuable manufacturing time.

Emissive crystals may be for example one or more of the following materials: metal carbides (such as Mo2C), metal borides (such as ZrB2, MoB2), metal silicides (such as ZrSi2, MoSi2, YSi2, LaSi2, ScSi2, NbSi2, RuSi2), or metals (such as Mo, Ru, Sc).

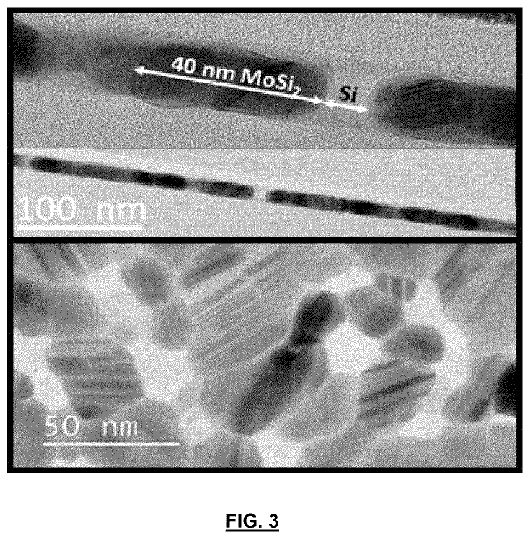

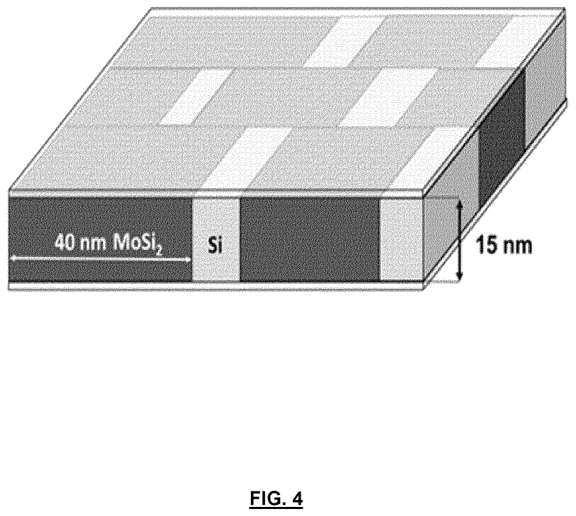

FIG. 3 is a transmission electron microscope image of a composite pellicle membrane in cross-section (upper 100 nm image) and in top-view (lower 50 nm image). As can be seen, the MoSi₂ crystals in the silicon matrix extend the full thickness of the pellicle membrane and so are susceptible to shocks. The large number of dislocations in the large emissive crystals are also visible. FIG. 4 is a schematic depiction showing how the large molybdenum disilicide crystals have a larger grain size, such as for example 40 nm, than the thickness of the pellicle membrane, such as for example 15 nm. The average grain size can be measured by measuring the largest length of the emissive crystals in a transmission electron microscope image and taking the average of the measurements from the crystals.

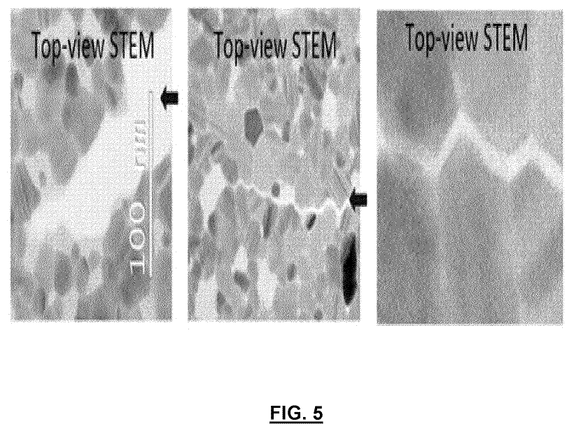

FIG. 5 is a top-view STEM image of a molybdenum silicide pellicle membrane. As can be seen, breakage of the membrane takes place along the boundaries of the grains of emissive crystals therein. Whilst multiple dislocations are visible in the STEM image, breakage occurs along grain boundaries rather than through individual grains. Whilst it may be considered that bulk nanocrystalline materials may display the inverse Hall-Petch regime, whereby making the crystal grains smaller would result in more creep and therefore a weaker pellicle, it has been realised that pellicle membranes may be considered as essentially 2D materials. It is predicted under the Hall-Petch regime that materials with larger grains have smaller yield stress resistance and that for small grains, diffusional creep and slipping of grains becomes dominant, leading to a weaker material. As such, according to the Hall-Petch regime and inverse Hall-Petch regime, grain sizes of from around 20 to around 40 nm are considered optimal in terms of yield strength and no improvement in yield strength is expected via a change in grain size, either increasing the size or decreasing the size. Even so, it has been observed that pellicles having such grain sizes are susceptible to shock, and the invention of the present disclosure solves this paradoxical issue. It has been found that pellicle membranes with a thickness of around 10 nm to around 30 nm which include emissive crystals of 10 nm or less, such as 8 to 10 nm, are less susceptible to shocks.

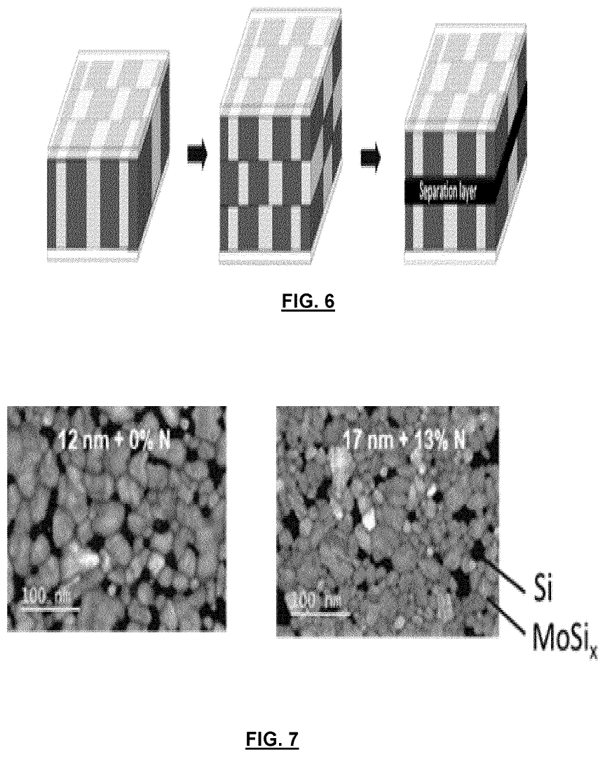

FIG. 6 depicts options for modifying a pellicle membrane to increase robustness. An existing pellicle membrane in which the emissive crystals (shown in light grey) extend across the entire thickness of the membrane is shown. Such a membrane has been shown to be susceptible to shocks, whereas the other two depicted pellicle membranes in accordance with the present disclosure are less susceptible to shock. In the second figure, it is shown that the grains of emissive crystals are smaller than the thickness of the pellicle membrane, such that more than one grain can be accommodated in the thickness of the pellicle membrane. Having the ability for there to be multiple grains of emissive crystal in the thickness of a pellicle membrane homogenises weak and strong bonds, and increases pellicle robustness. Similarly, the third figure depicts an embodiment in which there are two layers separated by a separation layer. The grains of emissive crystals are smaller than the thickness of the multi-layer pellicle membrane.

FIG. 7 depicts a comparison of the grain sizes of emissive molybdenum silicide crystals in a silicon matrix without and with additional nitrogen. As shown, the grains are larger and more rounded when no additional nitrogen is present and the grains are smaller and less rounded when 13 at % N is included. It will be appreciated that the crystals may be molybdenum disilicide or may be of the general formula MoSix.

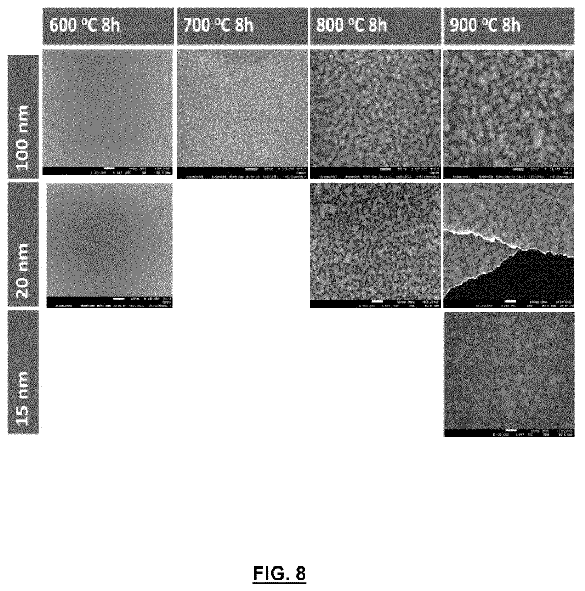

FIG. 8 shows various scanning electron microscopy images of pellicle membranes of different thicknesses which have been annealed at different temperature. As can be seen, crystal growth is observed in membranes which have been annealed for 8 hours at 700° C. The crystal grains are larger when the membrane has been annealed at higher temperatures for the same time. It has been found that the stress curve flattens as soon as the crystals start to form. Since it has been found that it is desirable to have crystals whose grain size is less than the thickness of the pellicle membrane, it is possible to select the crystal size by controlling the annealing temperature.

While specific embodiments of the invention have been described above, it will be appreciated that the invention may be practiced otherwise than as described.

The descriptions above are intended to be illustrative, not limiting. Thus it will be apparent to one skilled in the art that modifications may be made to the invention as described without departing from the scope of the claims set out below.

In summary, the present disclosure provides for pellicle membranes and components or apparatuses comprising such pellicle membranes which are more robust than existing pellicle membranes. This is achieved not solely by the size of the emissive crystal grains alone, but the combination of the size of the grains in combination with a lower thickness limit of the pellicle membrane. If the pellicle membrane thickness is so small that the grains span the thickness, making the pellicle membrane essentially one grain thick, then there is an elevated likelihood of weak spots, stress concentrations and the pellicle is consequently susceptible to mechanical shocks.

1. A pellicle membrane comprising thermally emissive crystals supported by a matrix, wherein the average thickness of the pellicle membrane is greater than the average grain size of the emissive crystals.

2. The pellicle membrane according to claim 1, wherein the thickness of the pellicle membrane is at least 1.5 times the average grain size of the emissive crystals.

3. The pellicle membrane according to claim 1, wherein the thickness of the pellicle membrane is in the range of from around 5 nm to around 30 nm.

4. The pellicle membrane according to claim 1, wherein the pellicle comprises MoSiSi—X, MoSiC—X or MoSiN—X, wherein X is selected from N, Y, O, S, C, Hf, Nb, W, Ta, Zr, or any combination selected therefrom.

5. The pellicle membrane according to claim 1, wherein the crystals comprise a content of around 20-22 at % Mo, and/or wherein the matrix and thermally emissive crystals define a core and the core comprises a content of around 3 to around 13 at % N.

6. The pellicle membrane according to claim 1, wherein the pellicle membrane includes at least two layers of single or multiple crystal grain thickness, separated by a separation layer.

7. The pellicle membrane according to claim 1, wherein the pellicle membrane includes a cap layer on one or both sides of the pellicle membrane.

8. The pellicle membrane according to claim 1, wherein the emissive crystals are nonrounded.

9. The pellicle membrane according to claim 1, wherein the average grain size of the emissive crystals is i) 20 nm or less, ii) from 1 to 20 nm, or iii) less than the thickness of the pellicle membrane divided by 1.5.

10. A pellicle assembly comprising the pellicle membrane according to claim 1.

11. A lithographic apparatus comprising the pellicle membrane according to any of claim 1.

12. A method of manufacturing a pellicle membrane including emissive crystals in a matrix, the method including controlling at least one selected from: the chemical composition of the emissive crystals, morphology of the emissive crystals, and/or annealing conditions, to provide a pellicle membrane having a thickness greater than the average grain size of the emissive crystals.

13. The method of claim 12, wherein the morphology of the emissive crystals is controlled such that the crystals are non-rounded.

14. The method of claim 12, wherein the emissive crystals include at least one metal, and wherein the concentration of the at least one metal is adjusted to control the grain size of the emissive crystals.

15. The method of claim 12, further comprising including nitrogen in a pellicle core to control the grain size of the emissive crystals.

16. The method of claim 12, comprising incorporating one or more selected from: N, Y, O, S, C, Hf, Nb, W, Ta, Zr, or any combination selected therefrom, in a pellicle core to control the grain size of the emissive crystals.

17. The method of any of claim 12, comprising controlling an the annealing temperature during manufacturing to control the grain size of the emissive crystals.

18. The method of any of claim 12, comprising providing at least two layers of separated by a separation layer wherein the thickness of one, both, or all of the layers is greater than the average grain size of the emissive crystals.

19. The method of claim 12, comprising controlling the morphology of the emissive crystals by including an element, to provide irregularly shaped grains.

20. (canceled)

21. A method comprising:
passing radiation through the pellicle membrane of claim 1; and
exposing a substrate to the radiation.
